(19) United States
(12) Patent Application Publication
(10) Pub. No.: US 2005/0276297 A1
(43) Pub. Date: Dec. 15, 2005

(54) Optical pickup and optical disk apparatus

(75) Inventors: Noriaki Nishi, Kanagawa (JP); Yoshiki Okamoto, Kanagawa (JP); Katsuhiro Seo, Kanagawa (JP); Satoshi Imai, Tokyo (JP); Kenji Yamamoto, Kanagawa (JP); Takeshi Yonezawa, Kanagawa (JP); Midori Kanaya, Tokyo (JP); Hiroaki Nakagawa, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Sony Corporation, Tokyo (JP)

(21) Appl. No.: 11/116,303

(22) Filed: Apr. 28, 2005

(30) Foreign Application Priority Data
May 14, 2004 (JP) 2004-145608

(51) Int. Cl. H01S 5/00

(52) U.S. Cl. 372/43.01

(57) ABSTRACT

An optical pickup includes a laser light source configured to emit laser light, an objective lens configured to focus the laser light emitted from the laser light onto an optical disk, and an image-formation magnification rate varying section for varying an image-formation magnification rate at which the laser light is focused on the optical disk.

### CROSS REFERENCE TO RELATED APPLICATONS

The present invention contains subject matter related to Japanese Patent Applications JP2004-145608, filed to the Japanese Patent Office respectively on May 14, 2004, the entire contents of which being incorporated herein by reference.

### BACKGROUND OF THE INVENTION

1. Field of the Invention

The present invention relates to an optical pickup and an optical disk apparatus which perform reading and writing of optical disks.

2. Description of Related Art

There are various formats (types) of optical disks such as CD (Compact Disc, a trademark), DVD (Digital Versatile Disc) and BD (Blu-ray Disc, a trademark).

Since it is convenient to perform reading and writing of such a plurality of formats of disks by means of the same optical disk apparatus, an optical disk apparatus capable of reading and writing both CD and DVD has been developed, such as the one described in Patent Document 1 (Japanese Patent Laid-Open Publication No. Hei9-161307)), for example.

### SUMMARY OF THE INVENTION

There are many cases where different formats of optical disks require objective lenses having different NAs (Numerical Apertures). In such case, if one objective lens is used to perform recording and reproducing of a plurality of formats of optical disks, the following inconveniences (1) to (3) may occur:

(1) The difference in NA between objective lenses causes a difference in optical coupling efficiency between their light source sides, so that there is a possibility that a peak of power on an optical disk deviates from an appropriate range. It is considered that as NA becomes smaller, optical coupling efficiency becomes smaller, so that the peak power on the optical disk is insufficient.

(2) A spot diameter on a light-receiving device depends on NA, so that there is a possibility that the difference in NA makes it difficult to detect a beam spot on the light-receiving device.

(3) Depth of focus, i.e., defocus margin, depends on NA, but a focus error pull-in range is approximately constant. Accordingly, there is a possibility that the difference in NA may become a cause of unbalance between the defocus margin and the pull-in range.

In addition, NAs for CD, DVD and BD are 0.51, 0.65 and 0.85, respectively, and if these three kinds of media are to be read and written, it is necessary to develop an optical disk apparatus capable of coping with a far wider range of NAs.

In view of the above-mentioned problems, the present invention has been conceived to provide an optical pickup and an optical disk apparatus both of which can easily address a difference between NAs of an objective lens.

According to a preferred embodiment of the present invention, there is provided an optical pickup which includes a laser light source which emits laser light, an objective lens which focuses the laser light emitted from the laser light onto an optical disk, and image-formation magnification rate varying unit for varying an image-formation magnification rate at which the laser light is focused on the optical disk.

The optical pickup may further include a second laser light source which is arranged close to the laser light source and emits second laser light to be focused onto the optical disk by the objective lens, at a wavelength different from that of the laser light emitted from the laser light source.

In the optical pickup, the image-formation magnification rate varying unit may have a lens and drive mechanism for driving the lens in the direction of an optical axis.

In optical pickup, the image-formation magnification rate varying unit may have a liquid crystal device.

The optical pickup may further include spherical-aberration correcting unit for correcting spherical aberration of the laser light.

In the optical pickup, the spherical-aberration correcting unit may have a lens and drive mechanism for driving the lens in the direction of an optical axis.

In the optical pickup, the spherical-aberration correcting unit may have a liquid crystal device.

The optical pickup may further include optical-axis correcting unit for correcting an optical axis of the laser light.

In the optical pickup, the optical-axis correcting unit may have a lens and drive mechanism for driving the lens in a perpendicular direction with respect to the optical axis.

In the optical pickup, the image-formation magnification rate varying unit may have drive mechanism for driving the lens in the direction of the optical axis.

In the optical pickup, the image-formation magnification rate varying unit and spherical-aberration correcting unit may be provided between the laser light source and the objective lens, the image-formation magnification rate varying unit may have a first lens and drive mechanism for driving the first lens in the direction of an optical axis, and the spherical-aberration correcting unit may have a second lens and drive mechanism for driving the second lens in the direction of the optical axis.

According to another preferred embodiment of the present invention, there is provided an optical disk apparatus which includes a laser light source which emits laser light, an objective lens which focuses the laser light emitted from the laser light source onto an optical disk, and image-formation magnification rate varying unit for varying an image-formation magnification rate at which the laser light is focused on the optical disk.

The optical disk apparatus may further include a second laser light source which is arranged close to the laser light source and emits second laser light to be focused onto the optical disk by the objective lens, at a wavelength different from that of the laser light emitted from the laser light source.

In the optical disk apparatus, the image-formation magnification rate varying unit may have a lens and drive mechanism for driving the lens in the direction of an optical axis.

In the optical disk apparatus, the image-formation magnification rate varying unit may have a liquid crystal device.

The optical disk apparatus may further include spherical-aberration correcting unit for correcting spherical aberration of the laser light.

In the optical disk apparatus, the spherical-aberration correcting unit may have a lens and drive mechanism for driving the lens in the direction of an optical axis.

In the optical disk apparatus, the spherical-aberration correcting unit may have a liquid crystal device.

The optical disk apparatus may further include optical-axis correcting unit for correcting an optical axis of the laser light.

In the optical disk apparatus, the optical-axis correcting unit may have a lens and drive mechanism for driving the lens in a perpendicular direction with respect to the optical axis.

As described above, according to the preferred embodiments of the present invention, it is possible to provide an optical pickup and an optical disk apparatus which may easily cope with a difference between NAs of an objective lens.

### BRIEF DESCRIPTION OF THE DRAWINGS

The above and other objects, features and advantages of the present invention will become more apparent from the following description of the presently preferred exemplary embodiments of the invention taken in conjunction with the accompanying drawings, in which:

FIG. 1 is a schematic view showing an optical pickup of an optical disk apparatus according to a first embodiment of the present invention;

FIG. 2 is a schematic view showing a zoom lens group according to a second embodiment of the present invention;

FIG. 3 is a schematic view showing a zoom lens group according to a modification 1 of the second embodiment of the present invention;

FIG. 4 is a schematic view showing a zoom lens according to a modification 2 of the second embodiment of the present invention; and

FIGS. 5A and 5B are schematic views showing different zoom lens groups according to a third embodiment of the present invention.

### DESCRIPTION OF THE PREFERRED EMBODIMENTS

Preferred embodiments of the present invention will be described below in detail with reference to the accompanying drawings.

### First Embodiment

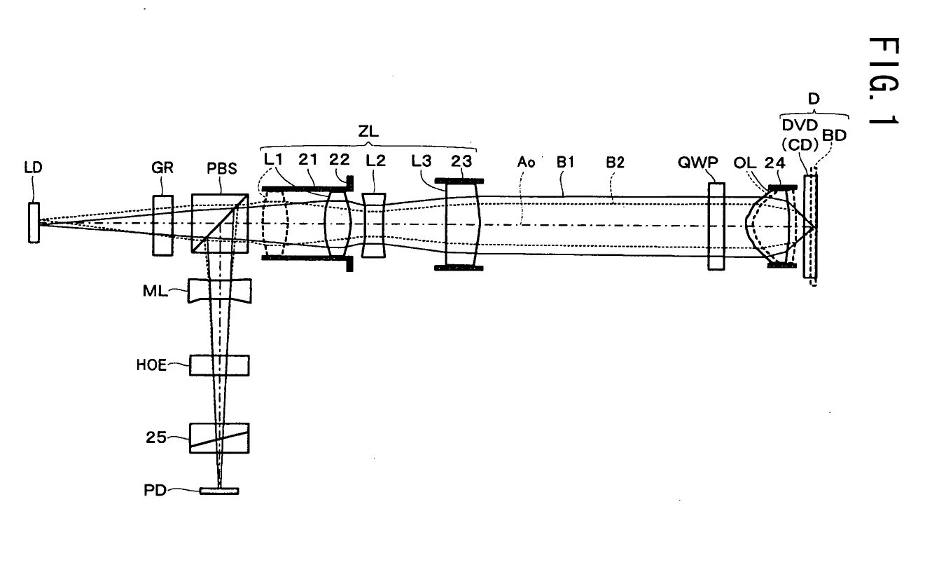

FIG. 1 is a schematic view showing an optical pickup 20 of an optical disk apparatus according to a first embodiment of the present invention.

The optical pickup 20 performs reading of information from a plurality of kinds of optical disks D based on different standards (CD (Compact Disc, a trademark), DVD (Digital Versatile Disc), BD (Blu-ray Disk) and the like).

The optical pickup 20 includes a laser diode LD, a grating GR, a polarizing beam splitter PBS, a zoom lens group ZL (lenses L1 to L3 and lens driving sections 21 to 23), a quarter wave plate QWP, an objective lens OL, an objective lens driving section 24, a multilens ML, a hologram device HOE, an optical-axis combination prism 25, and a photodiode PD, and performs reading of information from the optical disks D. In addition, a mirror M (not shown) may also be arranged, for example, between the zoom lens group ZL and the quarter wave plate QWP so as to bend the direction of laser light by 900.

The laser diode LD which serves as first, second and third laser light sources emits a first laser light of a first wavelength (λ1), a second laser light of a second wavelength (λ2), and a third laser light of a third wavelength (λ3). Examples of the first, second and third wavelengths are, respectively, 405 nm which is a first wavelength for reproduction of BD, 650 nm which is a second wavelength for reproduction of DVD, and 780 nm which is a third wavelength for reproduction of CD. The laser diode LD is made of a semiconductor chip, for example, in which are formed in proximity to one another, a first area which emits the first laser light (a first emission point), a second area which emits the second laser light (a second emission point), and a third area which emits the third laser light (a third emission point).

The grating GR is a three-wavelength-compatible diffraction grating which diffracts the first, second and third laser lights incident on the grating GR into different states in accordance with the first, second and third wavelengths. Each of the first, second and third laser lights is diffracted into a main beam and two sub-beams by the grating GR, and the main beam and the two sub-beams can be used to generate a tracking error signal (differential push-pull signal: DPP signal). For example, since BD, DVD and CD have different track pitches, the optimum angle between the three beams differs among BD, DVD and CD. Accordingly, different diffraction states are respectively set for the first, second and third wavelengths so that different optimum angles between the three beams can be formed. This setting is performed by appropriately setting the grating pitch, the groove depth and the like of the grating GR.

The polarizing beam splitter PBS is a polarizing device which allows passage of light polarized in a particular polarizing direction and reflects light polarized in polarizing directions perpendicular to the particular polarizing direction. The polarizing beam splitter PBS is combined with the quarter wave plate QWP so as to be set to reflect the first, second and third laser lights incident from the laser diode LD and to transmit the first, second and third laser lights reflected from the respective kinds of optical disks D.

The zoom lens group ZL is made of the lenses L1, L2 and L3 as well as the lens driving sections 21 to 23. The zoom lens group ZL is an optical device which converts the first to third laser lights emitted from the polarizing beam splitter PBS into parallel light beams, respectively, and. converts the first to third laser lights reflected from the respective kinds of optical disks D into convergent light beams. In addition, the zoom lens group ZL performs adjustment of image-formation magnification rate, correction of spherical aberration, and correction of optical axis tilt. Details of the zoom lens group ZL will be described later.

The quarter wave plate QWP gives phase difference to light being transmitted therethrough and converts linearly polarized light into circularly polarized light. A predetermined linearly polarized light which passes through the polarizing beam splitter PBS is converted into a circularly polarized light, and is reflected by the optical disks D as a circularly polarized light which rotates in an opposite direction. Accordingly, the circularly polarized light reflected by the optical disks D is converted into a linearly polarized light perpendicular to the predetermined linearly polarized light by passing through the quarter wave plate QWP, and the linearly polarized light is reflected by the polarizing beam splitter PBS and made incident on the photodiode PD.

The objective lens OL is an optical device which focuses any of the first, second and third laser lights onto the corresponding kind of optical disk D and converts laser light reflected from the optical disk D into a parallel light beam.

The objective lens OL is capable of focusing laser light onto any of the optical disks D having different depths to their respective recording layers, such as BD having a first protective substrate thickness, DVD having a second protective substrate thickness, and CD having a third protective substrate thickness.

The first protective substrate thickness of BD is 0.1 mm, the second protective substrate thickness of DVD is 0.6 mm, and the third protective substrate thickness of CD is 1.2 mm.

The first, second and third laser lights form beam spots SP1, SP2 and SP3 on the respective kinds of optical disks D. Numerical apertures NA at which the first, second and third laser lights are focused on the optical disks D are respectively set to NA1=0.85, NA2=0.65, and NA3=0.51. Namely, the respective numerical apertures NA1, NA2 and NA3 for the first, second and third laser lights are made smaller in that order (NA1>NA2>NA3).

Although not shown, this setting can be performed by arranging, for example, a diaphragm whose aperture varies for each of the first, second and third laser lights, in front of the objective lens OL (the size of the aperture of the diaphragm is made smaller in the order of the first, second and third laser lights). The diaphragm may use a mechanism which mechanically or optically adjusts a diaphragm. As an optical diaphragm adjustment mechanism, a three-wavelength diaphragm may be used in which optical materials having wavelength dependencies are patterned. Specifically, an optical adjustment mechanism for the diaphragm is prepared by patterning an optical material which transmits the first laser light of the first wavelength but does not transmit (reflects or absorbs) either of the second or third laser lights of the second or third wavelengths, and an optical material which transmits the first and second laser lights of the first and second wavelengths but does not transmit (reflects or absorbs) the third laser light of the third wavelength.

The lens driving section 24 is a mechanism for moving the objective lens OL in the forward and rearward directions and in a radial direction RD of each of the optical disks D. Namely, the lens driving section 24 performs focus adjustment (focusing) of each of the first, second and third laser lights as well as adjustment of a spot position (tracking).

The multilens ML is an optical device which gives astigmatism to the first, second and third laser lights. Namely, focus errors can be detected by an astigmatic method with the photodiode PD by the multilens ML giving astigmatism to each of the first, second and third laser lights.

In addition, the multilens ML is used for adjustment of image-formation magnification rate of optical feedback in an optical path for detecting reflected light (optical feedback) from the optical disks D. Namely, adjustment of focusing on the photodiode PD is performed by the multilens ML.

The hologram device HOE functions as optical-axis combination means in combination with the optical-axis combination prism 25.

The optical-axis combination means is an optical device for correcting each of the laser lights of the first, second and third wavelengths emitted from the laser diode LD with respect to the optical axis of an optical system of the optical pickup 20 and focusing each of the first, second and third laser lights on approximately the same position of the photodiode PD. There is a deviation between each of the emission points of the first, second and third laser lights, so that if, for example, the emission point of the first laser light is made coincident with the optical axis, the emission points of the second and third laser lights deviate from the optical axis. Accordingly, the first, second and third laser lights are respectively focused onto different positions on the photodiode PD. For this reason, the optical-axis combination means is used to adjust the optical path of each of the lights emitted from the first, second and third wavelengths so that the first, second and third laser lights are focused onto approximately the same position on the photodiode PD.

Specifically, the optical axes of the respective first, second and third laser lights can be corrected in the following manner.

The first laser light (the first wavelength) rectilinearly passes through both the hologram device HOE and the optical-axis combination prism 25, and reaches the optical device.

The second laser light (the second wavelength) is diffracted by the hologram device HOE and refracted by the optical-axis combination prism 25, and reaches the photodiode PD (the direction of the second laser light is varied by both the hologram device HOE and the optical-axis combination prism 25).

The third laser light (the third wavelength) rectilinearly passes through the hologram device HOE and is refracted by the optical-axis combination prism 25, and reaches the photodiode PD (the direction of the third laser light is varied by only the optical-axis combination prism 25).

In the above-mentioned manner, the first, second and third laser lights are focused onto approximately the same position on the photo diode PD. In addition, the optical-axis combination means may be made of a combination other than the combination of the hologram device HOE and the optical-axis combination prism 25.

The hologram device HOE is a diffraction grating which allows the laser lights of the first and second wavelengths to rectilinearly pass through, but diffracts the laser light of the second wavelength to vary the direction thereof.

The optical-axis combination prism 25 is an optical device which allows the laser light of the first wavelength to rectilinearly pass through, but refracts the laser lights of the second and third wavelengths (refracts the laser light of the third wavelength more than the laser light of the second wavelength). The optical-axis combination prism 25 may be prepared by cementing together two wedge-shaped optical glasses having approximately the same refractive index and different refractive-index dispersions with respect to the first wavelength.

The photodiode PD, which serves as a light-receiving device, is a device for detecting the first, second and third laser lights reflected by the respective kinds of optical disk D and performing reading of information from the optical disks D.

The photodiode PD has detection areas separated from one another so as to independently detect three beams which are a main beam and two sub-beams into which each of the laser beams is divided by the grating GR. The photodiode PD independently detects and calculates each of the three beams to generate a tracking error signal (differential push-pull signal: DPP signal) by a differential push-pull method (DPP method). In addition, the photodiode PD performs generation of a focus error signal by an astigmatic method.

(Operation of the Optical Pickup 20)

The operation of the optical pickup 20 will be described below. It is general practice to emit any one of the first, second and third laser lights according to the kind of optical disk D and the like, but in the following description, for ease of understanding, reference will be made to the first, second and third laser lights in a comparative manner.

(1) The first, second and third laser lights emitted from the laser diode LD are each divided into three beams by the grating GR, and the three beams pass through the polarizing beam splitter PBS and enter the zoom lens group ZL, in which the three beams are converted into a parallel light beam.

During emission from the laser diode LD, a beam B1 of the first laser light and a beam B2 of the second laser light do not necessarily coincide with an optical axis Ao of the optical pickup 20, but when the beams B1 and B2 pass through the zoom lens group ZL, the optical axes of the beams B1 and B2 are made coincident with the optical axis Ao (correction of optical axis tilt). In addition, when the beams B1 and B2 pass through the zoom lens group ZL, the diameters of the respective beams B1 and B2 are adjusted to correspond to the NA of the objective lens OL (improvement of optical coupling by adjustment of image-formation magnification rate). Furthermore, correction of spherical aberration is performed by the zoom lens group ZL. Details of such corrections will be described later.

(2) After that, the first, second and third laser lights enter the objective lens OL and are focused onto the respective kinds of optical disks D. For example, the first laser light is focused onto a BD and forms the beam spot SP1 thereon, the second laser light is focused onto a DVD and forms the beam spot SP2 thereon, and the third laser light is focused onto a CD and forms the beam spot SP3 thereon.

(3) The first, second and third laser lights reflected from the optical disks D pass through the objective lens OL and the zoom lens group ZL, and are reflected by the polarizing beam splitter PBS and pass through the multilens ML, so that astigmatism is given to the first, second and third laser lights.

(4) The first, second and third laser lights which have passed through the multilens ML are subjected to optical axis correction by passing through the hologram device HOE and the optical-axis combination prism 25, and the resultant laser lights having corrected optical axes enter the photodiode PD. The first, second and third laser lights are focused onto approximately the same position on the photodiode PD by the hologram device HOE and the optical-axis combination prism 25.

Signals corresponding to the three beams are outputted from the photodiode PD, and the three outputs are calculated to generate a tracking error signal (DPP signal), so that tracking control can be performed on the optical pickup 20 with the tracking error signal. In addition, the outputs from the photodiode PD are calculated and generation of a focus error signal by an astigmatic method is performed.

(Details of the Zoom Lens ZL)

Details of the zoom lens group ZL will be described below. The zoom lens group ZL makes it possible to perform adjustment of image-formation magnification rate, correction of spherical aberration, adjustment of an optical axis tilt, and the like.

A. Adjustment of Image-Formation Magnification Rate

First, the necessity of adjustment of image-formation magnification rate will be described below. Specifically, consideration will be given to the case where an ordinary collimator lens is used in place of the zoom lens group ZL, and the laser diode LD (light source) and the image-formation magnification rate on a recording surface of the optical disks D are approximately fixed.

In this case, there is a possibility that the following problems (1) to (3) occur because the NA of the objective lens OL differs according to the kind of optical disk D.

(1) The optical coupling efficiency between the laser diode LD and the optical disks D depends on the NA. When the NA is small, the optical coupling efficiency deteriorates, so that there is a possibility that the power of laser light on the optical disks D is insufficient.

(2) The spot diameter of laser light focused on the photodiode PD depends on the NA. When the NA is small, there is a possibility that the spot diameter becomes extremely small.

(3) The depth of focus, i.e., the defocus margin, depends on the NA. When the NA is small, the defocus margin becomes wide. On the other hand, since the pull-in range of focus errors is approximately constant, there is a possibility that unbalance occurs between the pull-in range and the defocus margin.

The depth of focus Df is inversely proportional to the square of the NA and proportional to a wavelength λ (the depth of focus Df˜λ/NA²). In the case of BD, DVD and CD, as the NA becomes smaller, the wavelength λ becomes longer, so that the depth of focus Df varies more greatly than in the case of only the NA.

(1), (2) and (3) will be specifically described below.

a) Regarding (1)

The optical coupling efficiency Rp, which depends on the divergence angle of each of the first, second and third laser lights emitted from the laser diode LD, is approximately proportional to the square of the NA on a light source side (the optical coupling efficiency Rp˜NA²). In general, the ratio of the NA on the light source side to the NA on an objective side is approximately constant.

Accordingly, the ratio of optical coupling efficiencies Rp1, Rp2 and Rp3 (Rp1:Rp2:Rp3) for BD, DVD and CD is 1.0:0.6:0.35, so that the optical coupling efficiencies Rp1, Rp2 and Rp3 greatly differ from one another.

During recording on the optical disks D, if the speed of recording becomes twofold, the peak power on the optical disks D needs to be multiplied by \sqrt{2}. Accordingly, a decrease in optical coupling efficiency leads to a decrease in recording speed.

In order to improve the optical coupling efficiencies, it can be considered to adopt a construction in which different optical paths for BD, DVD and CD are independently provided between the laser diode LD and the objective lens OL. However, this construction incurs increases in the number of components and the size of the optical pickup 20.

b) Regarding (2)

The ratio of spot diameters Rs1, Rs2 and Rs3 (Rs1:Rs2:Rs3) which are respectively formed on the photodiode PD when respectively using the BD, DVD and CD is 1.7:0.3:1, from the ratio of NAs on a photodiode PD side. This difference in the spot diameter Rs may become a problem in terms of the design of the photodiode PD.

c) Regarding (3)

When depths of field Df1, Df2 and Df3 are respectively calculated as to BD, DVD and CD from “Df˜λ/NA²”, the following results are obtained: Df1=0.56 μm, Df2=1.5 μm, and Df3=3.1 μm (Df1:Df2:Df3=1:3:6). Namely, the ratio of defocus margins M1, M2 and M3 for BD, DVD and CD becomes approximately 1:3:6. This difference in defocus margin is in an unallowable range even if it is taken into account that the difference is absorbed in the whole of an optical disk apparatus 10.

As mentioned above, if the image-formation magnification rate is fixed, there is a possibility that the difference in NA between the optical disks D incurs a decrease in optical coupling efficiency and the like.

In the first embodiment, the zoom lens group ZL is arranged between the laser diode LD (light source) and the optical disks D (recording medium) so that the image-formation magnification rate can be varied according to NA on the optical disks D, thereby preventing a decrease in optical coupling efficiency and the like.

Basically, it is possible to perform adjustment of the optical coupling efficiency by varying the image-formation magnification rate on a laser diode LD side (forward path) by means of the zoom lens group ZL. In addition, it is possible to perform adjustment of the focus error pull-in range and the like by varying the image-formation magnification rate on a photodiode PD side (backward path) by means of the zoom lens group ZL. Details of such adjustment will be described later.

The zoom lens group ZL of the optical pickup 20 is made of the three lenses L1, L2 and L3. The image-formation magnification rate can be varied by the lens L1 being moved by the lens driving section 21 in the direction of the optical axis. Spherical aberration can be corrected by the lens L3 being moved by the lens driving section 22 in the direction of the optical axis. An optical axis tilt can be corrected by the lens L1 being moved by the lens driving section 23 in the direction of the optical axis.

In addition, since both a convex lens and a concave lens are contained in the zoom lens group ZL, chromatic aberration correction can be easily designed.

Referring to FIG. 1, a BD and a DVD are arranged as the optical disks D as shown by solid lines and dashed lines, respectively, and the laser lights emitted from the laser diode LD and the arrangement of the zoom lens group ZL and the objective lens OL are adjusted according to the BD and the DVD. Specifically, the following difference exists between the solid lines and the dashed lines.

1) For the solid lines of FIG. 1, the first laser light of wavelength λ1 is emitted from the laser diode LD, while for the dashed lines of FIG. 1, the second laser light of wavelength λ2 is emitted from the laser diode LD. This relationship represents the relationship between wavelengths to be respectively used for recording and reproducing of the optical disks D.

In addition, the first and second laser lights differ in the divergence angles from the laser diode LD (the first laser light is narrower in divergence angle than the second laser light), and have an influence on optical coupling efficiency. This influence is not essential, but it is preferable to take the difference between the divergence angles into account during the adjustment of the image-formation magnification rate.

2) In the case of the solid lines of FIG. 1, the lens L1 of the zoom lens group ZL is positioned on a higher-magnification side, while in the case of the dashed line of FIG. 1, the lens L1 is positioned on a lower-magnification side.

The solid lines of FIG. 1 show that light exiting from the lens L1 is divergent light, while the dashed lines of FIG. 1 show that light exiting from the lens L1 is convergent light. The lights exiting from the lens L1 are respectively converted into parallel light beams by passing through the lenses L2 and L3. Accordingly, the light beams exiting from the lens L3, respectively shown by the solid and dashed lines in FIG. 1, differ in beam width (the light beam shown by the solid lines is wider than the light beam shown by the dashed lines), and correspond to an increase and a decrease in NA of the objective lens OL, thus leading to an improvement in optical coupling efficiency.

A variation in image-formation magnification rate Mp is carried out by the zoom lens group ZL in the following manner.

As NA becomes larger, the image-formation magnification rate Mp is made larger, while as NA becomes smaller, the image-formation magnification rate Mp is made smaller.

Preferably, this variation is made to correspond to the ratio of the inverses of NA for BD, DVD and CD (1/NA1:1/NA2:1/NA3), i.e., 1.3:1.0:0.78 (1/0.85:1/0.65:1/0.51).

More preferably, the variation is made to correspond to the ratio of the inverses of the squares of NA for BD, DVD and CD (1/NA12:1/NA22:1/NA32), i.e., 1.7:1.0:0.62 (1/0.8.52:1/0.652:1/0.512).

As the wavelength λ of laser light becomes shorter, the image-formation magnification rate Mp is made larger, while as the wavelength λ becomes longer, the image-formation magnification rate Mp is made smaller.

In the above-mentioned manner, it is possible to appropriately adjust the optical coupling efficiency according to the kind of optical disk D by varying NA on the light source side by means of the zoom lens group ZL.

Namely, when the optical disks D are exchanged, switching between the laser lights and a variation in the image-formation magnification rate are carried out. This variation is carried out during an off state in which focusing operation is stopped.

There is a case where although the optical disks D are not exchanged, the image-formation magnification rate is varied to vary the optical coupling efficiency.

During reproduction of the optical disks D, for example, it is possible to reduce the noise of the laser diode LD by decreasing the optical coupling efficiency (increasing the image-formation magnification rate). This setting is particularly useful when the optical disks D are of low reflectance.

When the output of laser light from the laser diode LD is increased, the SN ratio of laser light tends to increase (the noise of laser light is relatively decreased). Accordingly, during reproduction of the optical disks D, the S/N ratio of a reproduced signal to be outputted from the photodiode PD can be improved by increasing the output of laser light from the laser diode LD. At this time, if the optical coupling efficiency is decreased according to the increase of the output of laser light from the laser diode LD, the amount of light to be received by the photodiode PD can be adjusted to an appropriate range.

In addition, the rim/center intensity ratio (Rim Intensity) of laser light can be increased by decreasing the optical coupling efficiency (increasing the image-formation magnification rate). This setting is particularly useful when the optical disks D are of high recording density.

The rim/center intensity ratio represents the ratio of laser light intensity at the center (near the optical axis, or the center of the aperture) versus the rim (the edge of the aperture) of a beam of laser light. The intensity of laser light outputted from the laser diode LD assumes a Gaussian distribution in the radial direction of the laser light, so that as NA on the laser diode LD side is made smaller, the rim/center intensity ratio becomes larger. Namely, the intensity distribution of the laser light is equalized, and the reliability of reading of the optical disks D of high recording density is improved.

Furthermore, during switching between recording and reproducing, the image-formation magnification rate may be decreased, and when a high-speed continuous reproduction operation starts, the image-formation magnification rate may be increased so that a high S/N ratio can be ensured.

B. Adjustment of Focus Pull-in Range and Spot Diameter on Photodiode PD

The driving of the zoom lens group ZL causes a variation in NA on the photodiode PD side, thereby making it possible to adjust the pull-in range of focus and the spot diameter on the photodiode PD.

Assuming that L denotes the distance between a front focus and a rear focus and NAp denotes NA on the photodiode PD side, a pull-in range Spp and a spot diameter φ are expressed by the following formulas (1) and (2):
Spp˜(L/2)*(NAp/NA)² formula (1)
φ˜NAp*L formula (2)

Even for the same kind of optical disk D, focus errors having different pull-in ranges can be generated by varying the image-formation magnification rate Mp.

As the image-formation magnification rate Mp is made smaller, the pull-in range becomes wider. Accordingly, it is possible to reduce deterioration of a focus error signal when a variation or the like in spherical aberration occurs.

This adjustment can be used during the layer jump operation of the optical disks D on a multi-layer recording medium so as to stabilize the layer jump operation. Specifically, during the layer jump operation, the following operation is performed.

1) The tracking operation of the optical pickup 20 is stopped.

2) The lens L1 of the zoom lens group ZL is moved toward the lower-magnification side by the lens driving section 21, thereby decreasing the image-formation magnification rate.

3) Layer jump operation and spherical aberration correction are performed. Namely, the objective lens OL is driven to vary the depth of focus (beam spot) of laser light on the optical disks D. In addition, it is preferable to correct spherical aberration according to the variation in the depth of focus, by driving the lens L3. Correction of spherical aberration will be described later.

The image-formation magnification rate is small when the objective lens OL is driven. Accordingly, even if spherical aberration is not corrected during the driving of the objective lens OL, the deterioration of a focus error signal due to the spherical aberration is small. Accordingly, adjustment of focus (focusing) on a recording layer of the optical disks D is rapidly performed.

4) The lens L1 of the zoom lens group ZL is moved toward the higher-magnification side by the lens driving section 21, thereby increasing the image-formation magnification rate.

5) The tracking operation of the optical pickup 20 is again started.

In the above-mentioned manner, a layer jump can be rapidly carried out by decreasing the image-formation magnification rate during the layer jump. This operation is particularly useful when NA is large.

In addition, a diaphragm may be provided in an optical path which extends from the laser diode LD to the objective lens OL. The diaphragm can suppress aberrations which occur when the lens L1 is moved to the lower-magnification side.

C. Correction of Spherical Aberration

Spherical aberration can be corrected by the lens L3 of the zoom lens group ZL being moved by the LCD screen 23. There is a possibility that when the optical disks D are exchanged, spherical aberration becomes a problem as the result of variation in the depths of recording layers. For example, when the objective lens OL is driven according to the difference in depth between the recording layers so as to form a beam spot on one of the recording layers, there is a possibility that the beam spot is spread by spherical aberration. In this case, the lens L3 is driven to generate aberration components and cancel spherical aberration, thereby reducing the diameter of the beam spot.

D. Correction of Optical Axis Tilt

An optical axis tilt of laser light can be corrected by the lens L1 being moving (decentralized) in a perpendicular direction with respect to the optical axis, by the lens driving section 22.

The emission points of the first, second and third laser lights emitted from the laser diode LD are close to one another, but do not completely coincide with one another. Accordingly, the optical axes of the first, second and third laser lights do not completely coincide with another. The optical axes of the first, second and third laser lights can be made completely coincident by decentralizing the lens L1 with respect to each of the first, second and third laser lights (correction of an optical axis tilt on an objective-lens side.

In this case, a variation in the image-formation magnification rate and correction of the optical axis tilt can be carried out at the same time. At this time, the lens L1 moves in a direction oblique to the optical axis.

In addition, the correction of the optical axis tilt can also be performed by moving not the lens L1 but either of the lenses L2 or L3 in a perpendicular direction (or oblique) with respect to the optical axis. Otherwise, the optical axis tilt can also be corrected by moving two or all of the lenses L1, L2 and L3.

As can be seen from FIG. 1, at the time when the first, second and third laser lights are emitted from the laser diode LD, beams B of the first, second and third laser lights do not coincide with the optical axis Ao of the optical pickup 20, but the beams B are made to coincide with the optical axis Ao of the optical pickup 20 while the first, second and third laser lights are passing through the zoom lens group ZL, particularly, the lens L1.

E. Specification Example of Zoom Lens Group ZL

A specification example of the zoom lens group ZL will be described below.

First, the objective lens OL on which the zoom lens group ZL is premised will be described. Specifications of the objective lens OL are determined as follows.

As to the first, second and third laser lights, the NA of the objective lens OL is set to 0.85, 0.65 and 0.51, respectively, the focal length f [mm] of the objective lens OL is set to 1.766, and the effective radius φ [mm] (φ=f×2×NA) of the objective lens OL is set to 3.00, 2.29 and 1.79, respectively.

A specification example of the zoom lens group ZL will be described below.

For BD, the forward-path magnification is set to 10.3×, the backward-path magnification is set to 16.3×, and the beam diameter φ is set to 80 μm. For DVD and CD, the forward-path magnification is set to 5.9×.

The lens shift (moving amount) of the lens L1 is set to 3.42 mm. In addition, a difference of 110 μm in length between the emission points can be corrected by decentralizing the lens L1 by approximately 60 μm.

The stroke (moving distance) of the lens L3 is set to approximately ±1.5 mm. At this time, for BD, CG is approximately ±27 μm/drive ±27 mm, and for DVD, CG is approximately ±20 μm/drive ±1 mm.

CG means the cover layer thickness of each of the optical disks D (the distance from the surface to the recording layer of each of the optical disks D). For spherical aberration, the lens L3 needs to be moved on the basis of the cover layer thickness.

F. Alternative Embodiments

Light splitting means (for example, a beam splitter) is arranged between the zoom lens group ZL and the objective lens OL, and a monitoring light-receiving device (for example, the photodiode PD) receives split light and monitors light emitted from the laser diode LD, so that the output of the emitted light can be controlled (APC: Automatic Power Control).

In this modification, the aperture of a light beam incident on the monitoring light-receiving device may be made equivalent to the aperture of the objective lens OL. This constriction causes the light amount of a beam spot of laser light focused on the optical disks D by the objective lens OL to correspond to the light amount at the monitoring light-receiving device, thereby contributing to an improvement in the reliability of monitoring of the light amount of the beam spot.

The reason for this will be described below.

In the case where there is not a variation in the image-formation magnification rate of the zoom lens group ZL, even if the monitoring light-receiving device and the objective lens OL differ in aperture diameter, the ratio of a light amount incident on the monitoring light-receiving device to the light amount of a beam spot focused on the optical disks D by the objective lens OL is constant. Accordingly, the monitoring light-receiving device can monitor the light amount of the beam spot forced on the optical disks D.

Consideration will be given here to the case where when the monitoring light-receiving device and the objective lens OL differ in aperture diameter, the image-formation magnification rate is varied by the zoom lens group ZL. In this case, it is considered that even if the amount of light emitted from the laser diode LD is constant, the light amount of a beam spot focused on the optical disks D varies according to the image-formation magnification rate, and, on the other hand, the light amount incident on the monitoring light-receiving device hardly varies. For this reason, it is difficult for the monitoring light-receiving device to monitor the light amount of the beam spot focused on the optical disks D by the objective lens OL.

However, if the monitoring light-receiving device and the objective lens OL are made equivalent in aperture (their aperture diameters are made equal), the light amount incident on the monitoring light-receiving device and the amount of light emitted from the laser diode LD vary at the same ratio that the light amount of the beam spot focused on the optical disks D and the amount of light emitted from the laser diode LD vary with magnification. Accordingly, the light amount of the beam spot focused on the optical disks D by the objective lens OL can be reliably monitored and controlled.

### Second Embodiment

An optical disk apparatus according to a second embodiment of the present invention will be described below.

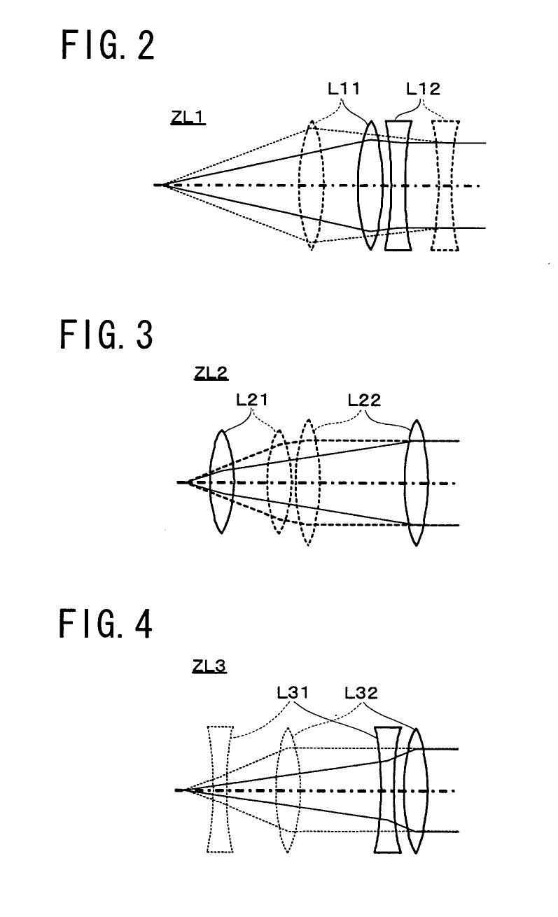

FIG. 2 is a schematic view showing a zoom lens group ZL1 of the optical disk apparatus. The second embodiment is similar to the first embodiment except the zoom lens group ZL1, and illustration of the entire construction of an optical disk apparatus 10a is omitted.

The zoom lens group ZL1 is a two-group lens system, and is made of lenses L11 and L12 arranged in that order from a closer side to the laser diode LD. The lens L11 is a convex lens, and the lens L12 is a concave lens. Image-formation magnification rate is varied by moving both the lenses L11 and L12, and in FIG. 2, solid lines and dashed lines correspond to higher-magnification setting and lower-magnification setting, respectively.

The zoom lens group ZL1 can ensure an amount of variation in image-formation magnification rate even if the moving amount of the lens L11 is not vary large, so that in design, it is easy to ensure a distance between the lens L11 and the polarizing beam splitter PBS. Namely, there is no risk that the lens L11 and the polarizing beam splitter PBS come into contact with each other during variation in image-formation magnification rate.

### Modification 1 of Second Embodiment

A modification 1 of the second embodiment of the present invention will be described below. In the modification 1, a zoom lens group ZL2 is used in place of the zoom lens group ZL1.

FIG. 3 is a schematic view showing the zoom lens group ZL2.

The zoom lens group ZL2 is a two-group lens system, and is made of lenses L21 and L22 arranged in that order from a closer side to the laser diode LD. Each of the lenses L21 and L22 is a convex lens. Image-formation magnification rate is varied by moving both the lenses L21 and L22, and in FIG. 3, solid lines and dashed lines correspond to higher-magnification setting and lower-magnification setting, respectively.

The zoom lens group ZL2 can ensure a distance between the lenses L21 and L22 during lower-magnification setting, so that the zoom lens group ZL2 is advantageous in correction of spherical aberration.

### Modification 2 of Second Embodiment

A modification 2 of a second embodiment of the present invention will be described below. In the modification 2, a zoom lens group ZL3 is used in place of the zoom lens group ZL1.

FIG. 4 is a schematic view showing the zoom lens group ZL3.

The zoom lens group ZL3 is a two-group lens system, and is made of lenses L31 and L32 arranged in that order from a closer side to the laser diode LD. The lens L31 is a concave lens, and the lens L32 is a convex lens. Image-formation magnification rate is varied by moving the lenses L31 and L32, and in FIG. 4, solid lines and dashed lines correspond to higher-magnification setting and lower-magnification setting, respectively.

### Third Embodiment

An optical disk apparatus 10b according to a third embodiment of the present invention will be described below.

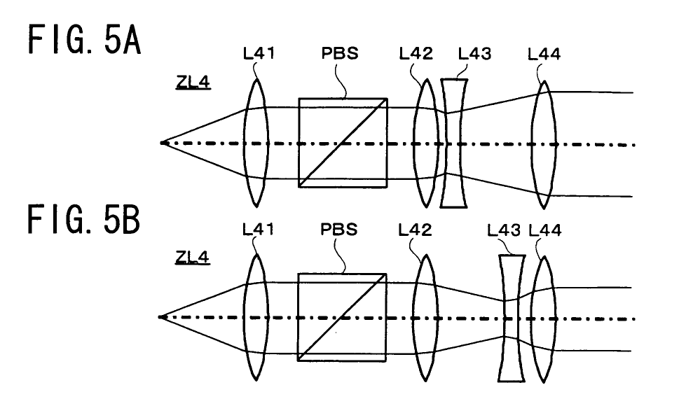

FIG. 5 is a schematic view showing a zoom lens group ZL4 of the optical disk apparatus 10b. FIGS. 5(a) and 5(b) correspond to higher-magnification setting and lower-magnification setting, respectively. The third embodiment is similar to the first embodiment except the zoom lens group ZL4, and illustration of the entire construction of the optical disk apparatus 10b is omitted.

The zoom lens group ZL4 is a four-group lens system, and is made of lenses L41 to L44 arranged in that order from a closer side to the laser diode LD. The lenses L41, L42 and L44 are convex lenses, and the lens L43 is a concave lens.

Laser light emitted from the laser diode LD side is converted into a parallel light beam by the lens L41 which serves as a collimator, and is converted by focal lenses L42 to L44 into parallel light beams having different effective diameters.

Variation in image-formation magnification rate is carried out by moving the lens L43 in the direction of the optical axis.

Correction of spherical aberration is carried out by moving the lens L44 in the direction of the optical axis or by moving the lenses L42 and L43 in mutually opposite directions along the optical axis. The former is based on a principle similar to the correction of spherical aberration by the lens L3 in the first embodiment, while the latter is based on a principle similar to correction of spherical aberration by a beam expander.

In the third embodiment, the polarizing beam splitter PBS is arranged in the parallel light beam. Accordingly, designing of the polarizing beam splitter PBS is facilitated. The reason for this will be described below.

In the first embodiment, the polarizing beam splitter PBS is arranged in divergent and convergent light beams. It is not easy to design the polarizing beam splitter PBS for a plurality of wavelengths corresponding to the divergent and convergent light beams, and there is a possibility that the designed polarizing beam splitter PBS undergoes characteristic deterioration such as angle dependency.

On the other hand, in the third embodiment, since the polarizing beam splitter PBS is arranged in the parallel light beam, the angle dependency of the characteristics of the polarizing beam splitter PBS hardly need be taken into account, so that the polarizing beam splitter PBS can be far more easily designed and manufactured.

### Other Embodiments

Although the preferred embodiments of the present invention are particularly described above, the present invention is not limited to the above-mentioned preferred embodiments. It will be obvious to those skilled in the art that various changes, modifications, combinations, sub combinations and alterations may be made depending on design requirements and other factors insofar as they are within the scope of the appended claims or equivalents thereof.

For example, a liquid crystal device can be used in place of a lens to converge and diverge light. If the liquid crystal device is used as the lens, convergence and divergence of light can be electrically controlled, so that the movement of the lens is not necessary.

In addition, the description of each of the embodiments has been made with reference to BD, CD and DVD, but the present invention can be similarly applied to not only such disks but also to other kinds of optical disks which differ from such disks in conditions such as wavelengths of disk laser light, numerical apertures NA of objective lenses, and depths to recording layers of disks.

1. An optical pickup comprising:
a laser light source configured to emit laser light;
an objective lens configured to focus the laser light emitted from the laser light onto an optical disk; and
image-formation magnification rate varying unit configured to vary an image-formation magnification rate at which the laser light is focused on the optical disk.

2. The optical pickup according to claim 1 further comprising a second laser light source arranged in a vicinity to the laser light source and configured to emit second laser light focused onto the optical disk by the objective lens, at a wavelength different from that of the laser light emitted from the laser light source.

3. The optical pickup according to claim 1, wherein the image-formation magnification rate varying unit further comprises a lens and drive mechanism configured to drive the lens in the direction of an optical axis.

4. The optical pickup according to claim 1, wherein the image-formation magnification rate varying unit further comprises a liquid crystal device.

5. The optical pickup according to claim 1 further comprising a spherical-aberration correcting unit configured to correct spherical aberration of the laser light.

6. The optical pickup according to claim 5, wherein the spherical-aberration correcting unit further comprises a lens and a drive mechanism configured to driving the lens in a direction of an optical axis.

7. The optical pickup according to claim 5, wherein the spherical-aberration correcting unit further comprises a liquid crystal device.

8. The optical pickup according to claim 1 further comprising an optical-axis correcting unit configured to correct an optical axis of the laser light.

9. The optical pickup according to claim 8, wherein the optical-axis correcting unit further comprises a lens and drive mechanism configured to drive the lens in a perpendicular direction with respect to the optical axis.

10. The optical pickup according to claim 9, wherein the image-formation magnification rate varying unit further comprises a drive mechanism configured to drive the lens in a direction of the optical axis.

11. The optical pickup according to claim 1, wherein:
the image-formation magnification rate varying unit and the spherical-aberration correcting unit are provided between the laser light source and the objective lens,
the image-formation magnification rate varying unit comprises a first lens and a drive mechanism configured to drive the first lens in a direction of an optical axis, and
the spherical-aberration correcting unit comprises a second lens and a drive mechanism configured to drive the second lens in a direction of the optical axis.

12. An optical disk apparatus comprising:
a laser light source configured to emit laser light;
an objective lens configured to focus the laser light emitted from the laser light source onto an optical disk; and
image-formation magnification rate varying unit configured to vary an image-formation magnification rate at which the laser light is focused on the optical disk.

13. The optical disk apparatus according to claim 12 further comprising a second laser light source arranged in the vicinity of the laser light source and configured to emit second laser light to be focused onto the optical disk by the objective lens, at a wavelength different from that of the laser light emitted from the laser light source.

14. The optical disk apparatus according to claim 12, wherein the image-formation magnification rate varying unit further comprises a lens and drive mechanism configured to drive the lens in a direction of an optical axis.

15. The optical disk apparatus according to claim 12, wherein the image-formation magnification rate varying unit comprises a liquid crystal device.

16. The optical disk apparatus according to claim 12 further comprising spherical-aberration correcting unit configured to correct spherical aberration of the laser light.

17. The optical disk apparatus according to claim 16, wherein the spherical-aberration correcting unit comprises a lens and drive mechanism configured to drive the lens in a direction of an optical axis.

18. The optical disk apparatus according to claim 16, wherein the spherical-aberration correcting unit comprises a liquid crystal device.

19. The optical disk apparatus according to claim 12 further comprising optical-axis correcting unit configured to correct an optical axis of the laser light.

20. The optical disk apparatus according to claim 19, wherein the optical-axis correcting unit comprises a lens and drive mechanism configured to drive the lens in a perpendicular direction with respect to the optical axis.
